(19) United States
(12) Patent Application Publication
(10) Pub. No.: US 2005/0140029 A1
(43) Pub. Date: Jun. 30, 2005

(54) Heterogeneous low k dielectric

(76) Inventors: Lih-Ping Li, Hsin-Chu (TW); Syun-Ming Jang, Hsin-Chu (TW); Pi-Tsung Chen, Tainan County (TW); Yung-Cheng Lu, Taipei (TW)

Correspondence Address: SLATER & MATSIL, L.L.P., 17950 PRESTON ROAD, SUITE 1000, DALLAS, TX, 75252, US

(21) Appl. No.: 10/975,238

(22) Filed: Oct. 28, 2004

Related U.S. Application Data
(60) Provisional application No. 60/533,481, filed on Dec. 31, 2003.

(51) Int. Cl. H01L 23/29

(52) U.S. Cl. 257/790

(57) ABSTRACT

The present invention provides for a heterogeneous low k dielectric comprising a main layer and a sub-layer. The main layer comprises a first low k dielectric material with a first low k dielectric constant and the sub-layer comprises a second low k dielectric material with a second low k dielectric constant. The sub-layer directly adjoins the main layer, and the second low k dielectric constant is greater than the first low k dielectric constant by more than 0.1.

This application claims the benefit of U.S. Provisional Application No. 60/533,481, filed on Dec. 31, 2003, entitled “Heterogeneous Low-k Dielectric Layer”, which application is hereby incorporated herein by reference.

### TECHNICAL FIELD

The present invention relates generally to semiconductor devices, and more particularly to a heterogeneous low k dielectric.

### BACKGROUND

In the continuing reduction of scale in integrated circuit structures, spacing between metal interconnects has decreased, resulting in increased parasitic capacitance between metal wires. Parasitic capacitance may cause signal propagation delay and may increase capacitive coupling, also known as “cross talk”, between metal wires. Silicon dioxide (SiO₂), with a dielectric constant (k) of about 3.9, has been used in the past to insulate metal wires. However, dielectric materials with dielectric constants lower than the dielectric constant of SiO₂, commonly referred to as low k materials, are being integrated into semiconductor manufacturing processes to lower the parasitic capacitance between metal wires in chip metal interconnection structures.

A dilemma exists however, in the use of known low k dielectric materials. One known control of the dielectric constant of a porous low k dielectric material is pore generation. An increase in porosity of a dielectric material may lower the dielectric constant, however, it also weakens other material properties such as hardness and density. The undesired weakening of the mechanical properties of a dielectric material may cause chip integrity and reliability problems. In addition, it may complicate the back end of line (BEOL) manufacturing process. Some manufacturing integration issues that exist with current low k dielectric materials include film delamination, peeling, and cracking during mechanically or thermally stressful processes such as chemical mechanical polish (CMP), chip packaging processes, and chip testing.

### SUMMARY OF THE INVENTION

Prior low k dielectric materials suffer from weak material properties causing manufacturing integration complexity and increased manufacturing cost. Therefore, a need exists for a low k dielectric material that may be integrated into a semiconductor manufacturing process with minimal susceptibility to thermally and mechanically stressful manufacturing and testing processes. These and other problems are generally solved or circumvented, and technical advantages are generally achieved, by illustrative embodiments of the present invention, which provides a heterogeneous low k dielectric and method of manufacturing.

In one aspect, the present invention provides for a heterogeneous low k dielectric comprising a main layer and a sub-layer. The main layer comprises a first low k dielectric material with a first low k dielectric constant and the sub-layer comprises a second low k dielectric material with a second low k dielectric constant. The sub-layer directly adjoins the main layer, and the second low k dielectric constant is greater than the first low k dielectric constant by more than 0.1.

In another aspect, the present invention provides for an integrated circuit. The integrated circuit comprises a substrate surface. The substrate surface comprises analog and digital semiconductor devices. Copper is over and affixed to the substrate surface. The integrated circuit further comprises a first layer having a first dielectric constant. The first layer is formed directly over the substrate surface. The integrated circuit also comprises a heterogeneous dielectric layer interposed between the first layer and the copper. The heterogeneous dielectric layer comprises a second layer with a second dielectric constant below about 3.9. The heterogeneous dielectric layer further comprises a third layer with a third dielectric constant below about 3.9. The second layer is interposed between the first and third layer and the second dielectric constant is intermediate the first and third dielectric constants.

In yet another aspect, the present invention provides for a system on a chip (SOC). The SOC comprises a substrate surface, a first insulator and a heterogeneous insulator. The substrate surface comprises surface features. The first insulator is directly over the substrate surface and has a first dielectric constant. The heterogeneous insulator directly overlays the first insulator and comprises a sub-layer and a main layer. The sub-layer has a first low k dielectric constant. The main layer has a second low k dielectric constant. The first low k dielectric constant is intermediate the first dielectric constant and the second low k dielectric constant.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1a is a cross-sectional view of a first illustrative embodiment of the present invention;

FIG. 1b is a cross-sectional view of a second illustrative embodiment of the present invention;

FIG. 1c is a cross-sectional view of a third and fourth illustrative embodiment of the present invention; and

FIG. 1d is a cross-sectional view of a fifth illustrative embodiment of the present invention.

### DETAILED DESCRIPTION OF ILLUSTRATIVE EMBODIMENTS

The making and using of the presently illustrative embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention.

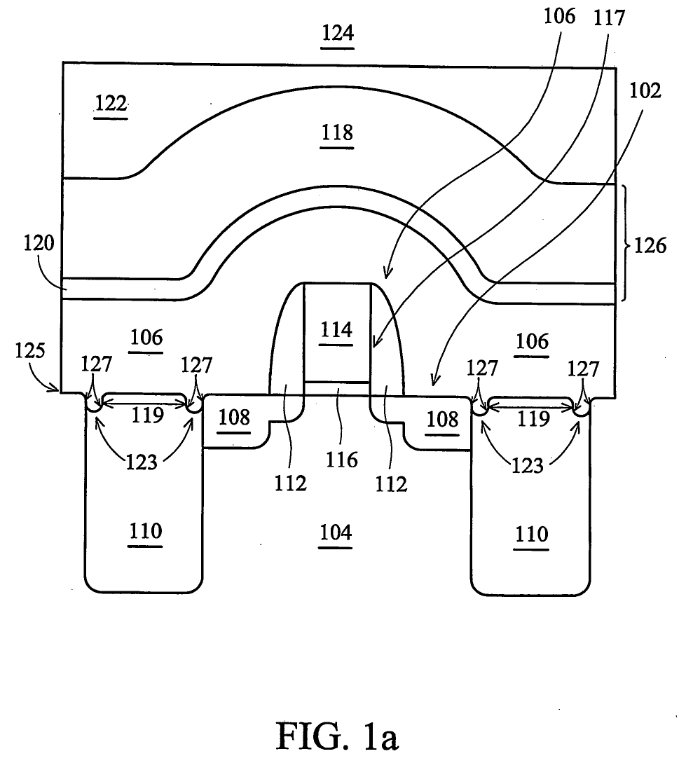

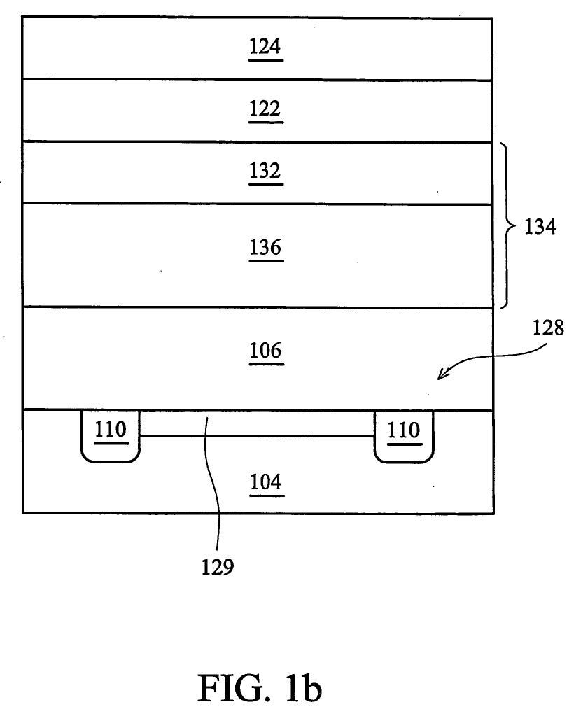

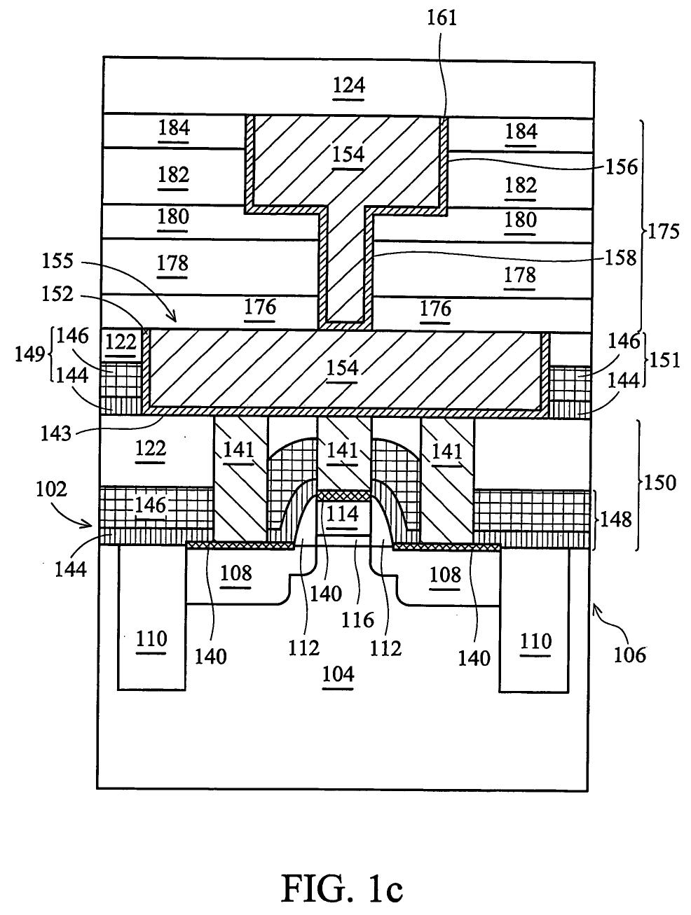

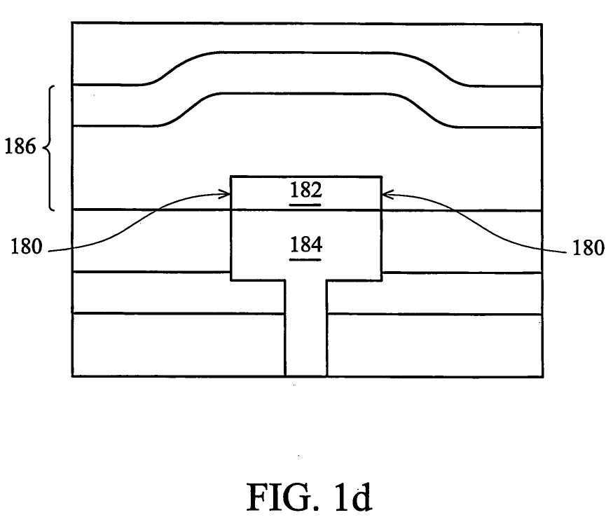

A method of manufacturing the first illustrative embodiment of the present invention is described below and shown in FIG. 1a. Front end of line (FEOL) manufacturing steps form a phosphorus-doped silicon glass (PSG) 100 directly over a substrate surface 102.

The substrate surface 102 includes a transistor 106 formed in an epitaxially grown semiconductor substrate 104. The source and drain 108 of the transistor 106 are bound by shallow trench isolation (STI) structures 110. Spacers 112 are formed on adjacent sides of the gate stack 117. The gate stack 117 comprises a gate electrode 114 and gate dielectric 116.

The low k sub-material 120 and the low k main material 118 are deposited using the formation parameters and material properties shown in table 1 below. Undoped silicon glass (USG) 122, formed directly overlaying the low k main material 118, is planarized by chemical mechanical polish. Subsequent metallization steps form overlying layers 124. The overlying layers 124 include metal wires insulated with inter-level dielectric materials.

TABLE 1
Formation Parameters and Material Properties of the First Illustrative
Embodiment

| | Heterogeneous low k dielectric | |
|---|---|---|
| | Low k | Low k |
| | Sub-material | Main Material |
| Type of Deposition | CVD | CVD |
| Deposition Temperature (° C.) | 300 | 300 |
| Oxygen source | O₂ | O₂ |
| Precursors | 3MS | 3MS |
| Deposition Chamber Pressure (torr) | 3T | 5T |
| HFRF Power/LFRF Power (watts) | 1000/100 | 600/80 |
| Anneal/Cure (° C.) | 300 | 300 |
| Dielectric Material | SiOCH | SiOCH |
| Dielectric Constant (k) | 2.7 | 2.5 |
| Thickness (Å) | 500 | 4000 |
| Porosity (%) | 20 | 35 |

Table 1 shows the type of deposition used in the manufacturing of the first illustrative embodiment. In other illustrative embodiments, the type of deposition includes any type of chemical vapor deposition (CVD) including plasma enhanced chemical vapor deposition (PECVD), high-density plasma chemical vapor deposition (HDP CVD), and low-pressure chemical vapor deposition (LPCVD), for example. Other illustrative embodiments include physical vapor deposition (PVD), atomic layer deposition (ALD), and spin-on deposition (SOD), for example. Still other illustrative embodiments include a combination of deposition methods, such as continuous multiple deposition and discontinuous multiple deposition with internal plasma treatment, for example. For example, continuous deposition may mean using the same precursor so that the deposition may be completed in situ. If deposition process is different (e.g., including CVD/Spin on process), a different precursor may be used, such as 3MS/O₂ forming a layer and then FSG forming a second layer, for example. Based on this process, the layer may be formed as a discontinuous deposition (i.e., not in situ). Deposition may be defined by the entry and exit of a wafer into a deposition chamber, for example. The above mentioned deposition methods use delivery systems such as gas and liquid, for example.

The low k sub-material 120 and the low k main material 118 form the heterogeneous low k dielectric 126 of the first illustrative embodiment. By having a dielectric constant intermediate the dielectric constant of the phosphorous-doped glass 100 and the dielectric constant of the low k main material 118, the low k sub-material 120 provides stress relief between the low k main material 118 and the phosphorous-doped glass 100. Because both materials 120 and 118 have a low k dielectric constant, the effective dielectric constant of the heterogeneous low k dielectric 126 is also a low k dielectric constant.

It should be noted that “low k” is a term used in the art typically used to refer to dielectric materials with a relative permittivity below the dielectric constant of thermally deposited silicon dioxide (SiO₂), which is about 3.9. Illustrative embodiments of the present invention use porous and non-porous low k materials, organic and inorganic low k materials, pure organic polymer low k materials, hybrid low k materials, parylenes, methylated silica, carbon doped siloxanes also known as organosilicate glass (OSG), SiCOH, fluorinated silicate glass (FSG), hydrogen silsesquioxane (HSQ), methyl silsesquioxane (MSQ), fluorinated amorphous carbon, SILk, FLARE, and Black Diamond, for example. Precursors used in other illustrative embodiments of the present invention include methylsilane (CH₃), dimethylsilane ((CH₃)₂SiH₂), trimethylsilane ((CH₃)₃SiH), tetramethylsilane ((CH₃)₄Si), oxygen (O₂), nitric oxide (NO), nitrous oxide (N₂O), nitrogen (N₂), and hydrogen peroxide (H₂O₂), for example.

A dielectric material used as an etch stop layer or as a dielectric diffusion barrier layer might be referred to as low k if it has a relative permittivity lower than the relative permittivity of silicon nitride, which is about 7. An example of a low k etch/barrier material is a silicon carbide based dielectric material with a relative permittivity of about 4.5.

Surface features 123 in the substrate surface 102 which are non-conformal to a horizontal plane 125, have steps 127. In the first illustrative embodiment, surface features 123 include the spacers 112, gate stack 117, and trench recesses 119. In other embodiments, steps are formed in conjunction with shallow trench isolation, localized oxidation of silicon (LOCOS), mesa isolation, and other active and passive substrate surface devices, for example. A conformal dielectric is preferable to provide a desired amount of electrical and mechanical passivity and material integrity, in addition to providing a desired level of step coverage. In the first illustrative embodiment, PSG 100 is deposited conformably over the substrate surface features 123, providing substantial control of substrate surface passivation.

The heterogeneous low k dielectric 126 of the first illustrative embodiment provides several advantages. More control of the parasitic capacitance between overlying metal layers 124 and the substrate surface 102 is achieved by using the heterogeneous low k dielectric 126. In addition, the low k sub-material 120 is a stress transition layer. The low k sub-material 120 is a stress transition layer, relieving stress by having a low k dielectric constant intermediate the low k dielectric constant of the low k main material 118 and the dielectric constant of the phosphorous-doped glass 100. Relieving material stress between the low k main material 118 and the underlying PSG material 100 is preventative of problems such as delamination, peeling and cracking.

A method of manufacturing the present invention in accordance with the second illustrative embodiment is shown in FIG. 1b. On a semiconductor wafer, the PSG material 100 is formed over a substrate surface 128, as shown in FIG. 1b. The substrate surface 128 includes a resistor 129 formed by ion implantation into the epitaxially grown silicon substrate 104. The resistor 129 is bound by shallow trench isolation structures 110. Table 2 below, shows the formation parameters and material properties used to deposit the low k main material 130 directly over the PSG material 100, followed by the deposition of the low k sub-material 132 directly over the low k main material 130. Undoped silicon glass (USG) 122 is formed directly overlaying the low k sub-material 132, followed by the formation of overlying metal layers 124.

TABLE 2
Formation Parameters and Material Properties in the Second Illustrative
Embodiment

| | Heterogeneous low k dielectric | |
|---|---|---|
| | Low k Main layer | Low k Sub-layer |
| Type of Deposition | CVD | CVD |
| Deposition Temperature (° C.) | 35 | 35 |
| Oxygen source | O₂ | O₂ |
| Hydrogen content | H₂ | H₂ |
| Precursors | 3MS | 3MS |
| Deposition Chamber Pressure (torr) | 3T | 5T |
| HFRF Power/LFRF Power (watts) | 1000/100 | 600/20 |
| Anneal/Cure (° C.) | 400 | 400 |
| Dielectric Material | SiOCH | SiOCH |
| Dielectric Constant (k) | 2.6 | 2.2 |
| Thickness (Å) | 2000 | 4000 |
| Porosity (%) | 15 | 35 |

The low k main material 130 and low k sub-material 132 form the heterogeneous low k dielectric 134 of the second embodiment. The heterogeneous low k dielectric 134 has a low k effective dielectric constant because the low k main material 130 and the low k sub-material 132 each have a low k dielectric constant. More control over the parasitic capacitance between overlying metal materials 124 and the substrate surface 128 is achieved by using the heterogeneous low k dielectric 134.

The low k main material 130 in FIG. 1b has a low k dielectric constant which is substantially less than the dielectric constant of the underlying PSG material 100. However, the bonding properties of the two materials 130 and 100 are sufficient to withstand subsequent thermally and mechanically stressful steps. The low k sub-material 132 improves adhesion between the low k main material 130 and the overlying USG material 122 because the low k sub-material 132 has a low k dielectric constant that is intermediate the low k dielectric constant of the low k main material 130 and the dielectric constant of the overlying USG material 122.

A cross-section of a semiconductor chip shown in FIG. 1c shows a third and fourth illustrative embodiment manufactured in a 90 nm process using copper metallization. The transistor structure in FIG. 1c has silicide 140 formed on the source 108, drain 108 and gate electrode 114. Table 3 shows the formation parameters and material properties used to deposit the low k sub-layer 144 followed by the low k main layer 146. The low k main layer 146 and the underlying low k sub-layer 144 form a first heterogeneous low k dielectric 148. Undoped silicon glass (USG) 122 formed directly over the heterogeneous low k dielectric layer 148, is planarized. The layer of undoped silicon glass 122 and the low k heterogeneous dielectric 148 form a first dielectric stack 150.

TABLE 3
Formation Parameters and Material Properties in the Third Illustrative
Embodiment

| | Heterogeneous low k dielectric | |
|---|---|---|
| | Low k | Low k |
| | Sub-material | Main Material |
| Type of Deposition | CVD | CVD |
| Deposition Temperature (° C.) | 35 | 35 |
| Oxygen source | O₂ | O₂ |
| Precursors | 4MS | 4MS |
| Deposition Chamber Pressure (torr) | 5T | 2T |
| HFRF Power/LFRF Power (watts) | 600/0 | 1200/100 |
| Anneal/Cure (° C.) | 400 | 400 |
| Dielectric Material | SiOCH | SiOCH |
| Dielectric Constant (k) | 2.2 | 2.5 |
| Thickness (Å) | 4000 | 2000 |
| Porosity (%) | 35 | 20 |

Tungsten plugs 141 are formed directly over the silicided source/drain 108 and silicided gate electrode 114 of the transistor 106. A second dielectric stack 151 with a second heterogeneous low k dielectric 149, is formed directly over the first dielectric stack 150. The first heterogeneous low k dielectric 148 in the surface passivation layer 150, in combination with the overlying second dielectric stack 151, form the third embodiment of the present invention.

A trench recess 143 is etched into the second dielectric stack 151 and a titanium nitride (TiN) liner 152 is deposited into the trench recess 143. Copper 154 is deposited by chemical vapor deposition to form a metal lead 155. The metal lead 155 is directly adjoined with the tungsten plugs 141, forming a conductive path from the first metal lead 155 to the source/drain 108 and gate electrode 114 of the transistor 106.

In the present embodiment, surface passivation and insulation of a first level of metal is achieved by stacking the first dielectric stack. In other embodiments, any number of heterogeneous low k dielectrics are vertically stacked in any combination with other dielectric materials and other heterogeneous low k dielectrics. For example, other illustrative embodiments have a vertical stack of co-terminus heterogeneous low k dielectrics, a vertical stack of varying heterogeneous low k dielectrics, and a vertical stack of co-terminus heterogeneous low k dielectrics interleaved with other inter-metal dielectrics (IMD), for example.

The first heterogeneous low k dielectric 148 of the third embodiment is a conformal dielectric, providing good step coverage over the substrate surface 102. The low k sub-layer 144 of the first heterogeneous low k dielectric 148 has a low k dielectric constant intermediate the dielectric constant of the substrate surface 102 and the low k dielectric constant of the low k main layer 146 of the first heterogeneous low k dielectric 148. As such, the low k sub-layer 144 of the first heterogeneous low k dielectric 148 is a stress transition layer, providing stress relief and a desired level of adhesion between the substrate surface 102 and the low k main layer 146 of the first heterogeneous low k dielectric 148.

FIG. 1c shows the heterogeneous low k dielectric 175 of the fourth embodiment deposited over the second dielectric stack 151 of the third embodiment according to the following sequence, with the formation parameters and material properties shown in table 4: a first low k sub-layer 176, a first low k main layer 178, a second low k sub-layer 180, a second low k main layer 182, and a third low k sub-layer 184.

TABLE 4
Formation Parameters and Material Properties in the Fourth Illustrative
Embodiment

| | Heterogeneous Low k Dielectric | | | | |
|---|---|---|---|---|---|
| | First | First | Second | Second | Third |
| | Low | Low | Low | Low | Low |
| | k Sub- | k Main | k Sub- | k Main | k Sub- |
| | layer | Layer | layer | Layer | layer |
| Type of Deposition | CVD | CVD | CVD | CVD | |
| Deposition | 400 | 335 | 350 | 335 | |
| Temperature (° C.) | | | | | |
| Oxygen source | O₂ | O₂ | O₂ | O₂ | |
| Hydrogen content | | | | | H₂ |
| Precursors | FSG | 3MS | 4MS | 3MS | |
| Deposition | 3T | 3.5T | 2T | 3.5T | |
| Chamber Pressure | | | | | |
| (torr) | | | | | |
| HFRF Power/ | 800/0 | 600/80 | 1200/200 | 600/80 | 2000 |
| LFRF Power (watts) | | | | | |
| Anneal/Cure (° C.) | 400 | 335 | 350 | 335 | 400 |
| Dielectric Material | FSG | SiCOH | SiCOH | SiCOH | SiCOH |
| Dielectric Constant | 3.5 | 3.0 | 4.5 | 3.0 | 3.4 |
| (k) | | | | | |
| Thickness (Å) | 1000 | 2000 | 500 | 3000 | 200 |
| Porosity (%) | <10 | 20 | <5 | 20 | <10 |

Using a via-first dual damascene approach, CxFy/O₂ is used to etch a trench 156 recess and a via 158 recess into the heterogeneous low k dielectric 175, for example. A barrier layer 161 of tantalum nitride (TaN) 161 is deposited followed by the deposition of copper (Cu) 154. The TaN 161 and Cu 154 fill the trench 156 and via 158 recesses as shown in FIG. 1c. The top surface of the heterogeneous low k dielectric 175 is planarized by chemical mechanical polish to form a substantially flat surface upon which additional trench and via layers 124 are formed.

The method of manufacturing the fourth illustrative embodiment includes a via-first dual damascene process. Other illustrative embodiments of the present invention use dual damascene processes known as buried mask and trench-first, for example. In other embodiments the copper process is a single damascene process. Yet other illustrative embodiments use an aluminum process employing subtractive etch, and still others use a combination of aluminum and copper metallization processes.

The first low k sub-layer 176 of the fourth illustrative embodiment is a dielectric barrier layer, substantially limiting the diffusion of copper ions from the copper 154 into the first low k main layer 178. In addition, the first low k sub layer 176 provides stress relief between the first low k main layer 178 and the underlying copper 154 and silicon oxide 122 by having a low k dielectric constant intermediate the low k dielectric constant of the first low k main layer 178 and the dielectric constants of the underlying copper 154 and undoped silicon glass 122 of the second dielectric stack 151.

The second low k sub-layer 180 is an etch stop layer. The second low k sub-layer 180 provides etchant selectivity, enabling control of recess 156, 158 formation and depth. The second low k sub-layer 180 has a low k dielectric constant intermediate the dielectric constant of the first low k main layer 178 and the low k dielectric constant of the second low k main layer 182, thereby providing stress relief between the layers 178 and 182.

The third low k sub-layer 184 is an encapsulation (cap) layer designed to protect the second low k main layer 182 from the harmful effects of chemical mechanical polish. In addition, the third low k sub-layer 184 provides stress relief between the second low k main layer 182 and overlying metallization layers 124 by having a low k dielectric constant intermediate the dielectric constants of the two layers 182 and 124.

The low k heterogeneous dielectric 175 is a low k inter-layer dielectric (ILD), also referred to as a low k inter-metal dielectric (IMD), providing a low relative permittivity between vertically and horizontally spaced copper wires. By providing low k sub-layers 176, 180 and 184 with intermediate low k dielectric constants, structural integrity is achieved in the chip's metal structure, and harmful defects such as delamination, peeling and cracking are less likely to occur.

FIG. 1d shows steps 180 formed by the deposition of a selective etch-stop/barrier layer 182 over copper 184. The heterogeneous low k dielectric 186 can be deposited conformably over the steps 180.

Although the present invention and its advantages have been described in detail, it should be understood that various changes, substitutions and alterations may be made herein without departing from the spirit and scope of the invention as defined by the appended claims. It will be readily understood by those skilled in the art that the present invention may be varied while remaining within the scope of the present invention. For example the present invention may be used in any type of capacitor and other semiconductor device or structure requiring dielectric material, such as micro-electrical mechanical semiconductor (MEMS) devices, for example. In addition, the present invention may be used in non-semiconductor capacities, including lenses, windows, or other objects or processes requiring dielectric film.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A heterogeneous low k dielectric comprising:
a main layer comprising a first low k dielectric material with a first low k dielectric constant;
a sub-layer comprising a second low k dielectric material with a second low k dielectric constant, the sub-layer directly adjoining the main layer, and the second low k dielectric constant greater than the first low k dielectric constant by more than 0.1.

2. The heterogeneous low k dielectric of claim 1, wherein the second low k dielectric constant is greater than the first dielectric constant by more than about 0.3.

3. The heterogeneous low k dielectric of claim 1, wherein the thickness of the second low k dielectric material is less than about 1000 angstroms and the thickness of the first low k dielectric material ranges between about 1000 angstroms and 1 micron.

4. The heterogeneous low k dielectric of claim 1, wherein the thickness of the second low k dielectric material is less than about 500 angstroms and the thickness of the first low k dielectric material ranges between about 1000 to 5000 angstroms.

5. The heterogeneous low k dielectric of claim 1, wherein the first low k material has a first porosity, the second low k material has a second porosity, the first porosity is less than or equal to about 80%, the second porosity is less than or equal to about 40%, and the first porosity is greater than the second porosity.

6. The heterogeneous low k dielectric of claim 1, wherein the sub-layer has a density greater than a density of the main layer.

7. The heterogeneous low k dielectric of claim 1, wherein the sub-layer has a hardness greater than a hardness of the main layer.

8. The heterogeneous low k dielectric of claim 1, wherein the sub-layer is a member elected from the group consisting of etch stop layer, dielectric barrier layer, passivation layer, conformal dielectric layer, stress transition layer, encapsulation layer, and combinations thereof.

9. An integrated circuit comprising:
a substrate surface comprising analog and digital semiconductor devices;
copper over the substrate surface and affixed to the substrate surface;
a first layer having a first dielectric constant, the first layer formed directly over the substrate surface; and
a heterogeneous dielectric layer interposed between the first layer and the copper, the heterogeneous dielectric layer comprising:
a second layer with a second dielectric constant below about 3.9; and
a third layer with a third dielectric constant below about 3.9, the second layer interposed between the first and third layer and the second dielectric constant intermediate the first and third dielectric constants.

10. The integrated circuit of claim 9, wherein the second dielectric constant is greater than the third dielectric constant by more than 0.1.

11. The integrated circuit of claim 9, wherein the second dielectric constant is greater than the third dielectric constant by more than 0.3.

12. The integrated circuit of claim 9, wherein the thickness of the second layer is less than about 4000 angstroms and the thickness of the third layer ranges between about 1000 angstroms and 1 micron.

13. The integrated circuit of claim 9, wherein the thickness of the second layer is less than about 4000 angstroms and the thickness of the third layer ranges between about 1000 to 5000 angstroms.

14. The integrated circuit of claim 9, wherein the heterogeneous dielectric layer is formed over one or more steps.

15. The integrated circuit of claim 9, wherein the second layer further having a first porosity, the third layer having a second porosity, the first porosity is less than or equal to about 40%, the second porosity is less than or equal to about 80%, and the first porosity is less than the second porosity.

16. The integrated circuit of claim 9, wherein the second layer has a density greater than a density of the third layer.

17. The integrated circuit of claim 9, wherein the second layer has a hardness greater than a hardness of the third layer.

18. The integrated circuit of claim 9, wherein the second layer is a member elected from the group consisting of etch stop layer, dielectric barrier layer, passivation layer, conformal dielectric layer, stress transition layer, encapsulation layer, and combinations thereof.

19. A system on a chip (SOC) comprising:
a substrate surface comprising surface features;
a first insulator directly over the substrate surface, the first insulator having a first dielectric constant; and
a heterogeneous insulator directly overlying the first insulator, the heterogeneous insulator comprising:
a sub-layer with a first low k dielectric constant; and
a main layer with a second low k dielectric constant, the first low k dielectric constant intermediate the first dielectric constant and second low k dielectric constants.

20. The SOC of claim 19, wherein the first low k dielectric constant is greater than the second low k dielectric constant by more than 0.1.

21. The SOC of claim 19, wherein the first low k dielectric constant is greater than the second low k dielectric constant by more than 0.3.

22. The SOC of claim 19, wherein the thickness of the sub-layer is less than about 1000 angstroms and the thickness of the main layer ranges between about 1000 angstroms and 1 micron.

23. The SOC of claim 19, wherein the thickness of the sub-layer is less than about 1000 angstroms and the thickness of the main layer ranges between about 1000 to 5000 angstroms.

24. The SOC of claim 19 further comprising a metal wire structure, the heterogeneous insulator formed over greater than 90% of the area of the metal wire structure and over one or more steps.

25. The SOC of claim 19, wherein the sub-layer has a first porosity and the main layer has a second porosity, the first porosity is less than or equal to about 40%, the second porosity is less than or equal to about 80%, and the second porosity is greater than the first porosity.

26. The SOC of claim 19, wherein the sub-layer has a density greater than a density of the main layer.

27. The SOC of claim 19, wherein the sub-layer has a hardness greater than a hardness of the main layer.

28. The SOC of claim 19, wherein the sub-layer is a member elected from the group consisting of etch stop layer, dielectric barrier layer, passivation layer, conformal dielectric layer, stress transition layer, encapsulation layer, and combinations thereof.

29. An integrated circuit comprising:
a substrate surface having a first dielectric constant;
wires overlying and affixed to the substrate surface;
a heterogeneous low k dielectric layer comprising:
a sub-layer directly over the substrate surface with a second dielectric constant, the second dielectric constant below 3.9 and less than the first dielectric constant; and
a main layer directly overlying the sub-layer, the main layer having a third dielectric constant, the third dielectric constant below 3.9 and less than the second dielectric constant by at least 0.1, and the second dielectric constant intermediate the first and third dielectric constants; and
a dielectric layer having a fourth dielectric constant, the heterogeneous low k dielectric layer interposed between the substrate surface and the dielectric layer, the fourth dielectric constant greater than the third dielectric constant, and the dielectric layer and underlying heterogeneous low k dielectric layer forming a substrate surface passivation insulator interposed between the overlying wires and the underlying substrate surface.

30. The integrated circuit of claim 29, wherein the second dielectric constant is greater than the third dielectric constant by at least about 0.3.

31. The integrated circuit of claim 29, wherein a sub-layer thickness is less than about 1000 angstroms and a main layer thickness is intermediate about 1000 angstroms and 1 micron.

32. The integrated circuit of claim 29, wherein a sub-layer thickness is less than about 4000 angstroms and a main layer thickness is intermediate about 1000 to 5000 angstroms.

33. The integrated circuit of claim 29, wherein the heterogeneous low k dielectric layer is formed over one or more surface features.

34. The integrated circuit of claim 29, wherein the main layer further comprises a first porosity less than or equal to about 80%, the sub-layer further comprises a second porosity less than or equal to about 40%, and the first porosity is greater than the second porosity.

35. The integrated circuit of claim 29, wherein the sub-layer has a density greater than a density of the main layer.

36. The integrated circuit of claim 29, wherein the sub-layer has a hardness greater than a hardness of the main layer.

37. The integrated circuit of claim 29, wherein the sub-layer is a member elected from the group consisting of etch stop layer, dielectric barrier layer, passivation layer, conformal dielectric layer, stress transition layer, encapsulation layer, and combinations thereof.

38. A semiconductor wafer including:
a substrate with analog devices and complementary metal oxide semiconductor (CMOS) devices formed therein;
a conformal insulator formed directly over the substrate;
a metal structure over the conformal insulator and affixed to the analog and CMOS devices to form analog and digital circuits; and
a heterogeneous low k dielectric comprising a main layer and a sub-layer, the heterogeneous low k dielectric interposed between the conformal dielectric and metal structure, the heterogeneous low k dielectric also formed over 90% of the area of the metal structure and over a plurality of steps, and the main layer and the sub-layer each having a porosity, density, hardness, dielectric constant, and thickness such that:
the porosity of the main layer is less than or equal to 80%, the porosity of the sub-layer is less than 40%, and the porosity of the main layer is greater than the porosity of the sub-layer;
the density of the main layer is less than the density of the sub-layer;
the hardness of the main layer less than the hardness of the sub-layer;
the dielectric constant of the main layer is less than the dielectric constant of the sub-layer by at least 0.3; and
the thickness of the main layer is in a range between about 4000 angstroms and about 1 um, and the thickness of the sub-layer is less than or equal to about 1000 angstroms.

39. A copper interconnect structure comprising:
a heterogeneous low k dielectric with a first and second main layer formed over 90% of the area of the copper interconnect structure and over a plurality of steps, the first main layer formed in a trench layer of the copper interconnect structure, the second main layer formed directly under the first main layer in a via layer of the copper interconnect structure, the first and second main layers each having a porosity, a dielectric constant, and a thickness such that the porosities of the first and second main layers are less than or equal to about 80%, the porosity of the first main layer is greater than the porosity of the second main layer, the thicknesses of the first and second main layers are greater than about 1000 angstroms and less than about 1 um, and the dielectric constants of the first and second main layers are below about 3.9.

40. A semiconductor metal system comprising:
a trench layer and a via layer, the trench layer directly overlying the via layer;
a heterogeneous low k dielectric comprising:
a first main layer in the trench layer, the first main layer having a first main layer porosity, a first main layer density, a first main layer hardness, a first main layer dielectric constant, and a first main layer thickness;
a second main layer in the via layer, the second main layer having a second main layer porosity, a second main layer density, a second main layer hardness, a second main layer dielectric constant, and a second main layer thickness;
a first sub-layer directly underneath the first main layer and having a first sub-layer porosity, a first sub-layer density, a first sub-layer hardness, a first sub-layer dielectric constant, and a first sub-layer thickness;
a second sub-layer directly interposed between the first main layer and second main layer, the second sub-layer having a second sub-layer porosity, a second sub-layer density, a second sub-layer hardness, a second sub-layer dielectric constant, and a second sub-layer thickness;
a third sub-layer directly over the second main layer, the third sub-layer having a third sub-layer porosity, a third sub-layer density, a third sub-layer hardness, a third sub-layer dielectric constant, and a third sub-layer thickness; and
the first main layer porosity being greater than the second main layer porosity, the first and second main layer porosities being less than or equal to about 80%, the first, second and third sub-layer porosities being less than 40%, the first and second main layer porosities being greater than the first, second and third sub-layer porosities, the first and second main layer densities being less than the first, second and third sub-layer densities, the first and second main layer hardnesses being less than the first, the first and second main layer dielectric constants being less than the first, second and third sub-layers dielectric constants by at least about 0.3, the first and second main layer thicknesses being in a ranges between about 1000 angstroms and less than about 1 um, the first, second and third sub-layer thicknesses being less than or equal to about 4000 angstroms.

41. A pre-metal dielectric film comprising:
a conformal dielectric layer comprising phosphorous-doped silicon glass material with a first dielectric constant between about 3.9 and about 4.5;
a heterogeneous dielectric film having an effective dielectric constant below about 3.9, the heterogeneous dielectric film formed directly over the conformal dielectric layer, the heterogeneous dielectric film comprising:
a sub-layer with a second dielectric constant below about 3.9; and
a main layer with a third dielectric constant below about 3.9, the sub-layer directly underlying the main layer and directly overlying the conformal dielectric layer, the second dielectric constant intermediate the first and second dielectric constants; and
a layer of substantially undoped silicon glass having a dielectric constant between about 3.9 and about 4.5, the layer of undoped silicon glass directly over the heterogeneous dielectric film.

42. A method of forming a heterogeneous low k dielectric, the method comprising:
forming a first semiconductor material with a first dielectric constant;
forming a first dielectric material directly over the first semiconductor material, the first dielectric material having a second dielectric constant less than the first dielectric material and less than about 3.9; and
forming a second dielectric material directly over the first dielectric material, the second dielectric material having a third dielectric constant less than the second dielectric constant and less than about 3.9.

43. The method of claim 42, wherein the first and second dielectric materials are formed with a high temperature deposition process, the temperature greater than or equal to about 150° C.

44. The method of claim 42, wherein the first and second dielectric materials are formed with a low temperature deposition process, the temperature less than or equal to about 150° C.

45. The method of claim 42, wherein the porosity of the first and second dielectric materials substantially control the second and third dielectric constants, respectively.

46. The method of claim 42, wherein the first material is formed by flowing 3MS/O₂ into a deposition chamber at a gas flow rate between about 1600-500 sccm and about 600-300 sccm.

47. The method of claim 42, wherein the second material is formed by flowing 3MS/O₂ into a deposition chamber at a gas flow rate between about 1200-500 sccm and about 1200-300 sccm.

48. The method of claim 42, further comprising an anneal process performed at about 150-400° C.

49. The method of claim 42, further comprising an E-beam curing process performed at about 200-400° C.

50. The method of claim 42, further comprising a plasma curing process performed at about 150-400° C.
